(19) United States
(12) Patent Application Publication
(10) Pub. No.: US 2024/0110627 A1
(43) Pub. Date: Apr. 4, 2024

(54) SEALED LAMINATED WINDOW UNIT

(71) Applicant: DelStar Technologies, Inc., Alpharetta, GA (US)

(72) Inventor: Nandan Ukidwe, Suffield, CT (US)

(21) Appl. No.: 18/477,432

(22) Filed: Sep. 28, 2023

Related U.S. Application Data
(60) Provisional application No. 63/412,129, filed on Sep. 30, 2022.

(51) Int. Cl. F16J 15/12; H01L 31/0224; H01L 31/0468; H05K 1/05

(52) U.S. Cl. CPC F16J 15/128; H01L 31/022466; H01L 31/0468; H05K 1/05; B32B 15/095

(57) ABSTRACT

A seal is provided for enclosing an edge of a laminated structure. The seal may comprise a polymeric base layer, a foil layer, and a plurality of photovoltaic cells disposed on the foil layer. The seal may be adhered to an edge of a laminate that has luminescent solar concentrators for harvesting energy from light. The laminate may be a glass laminate, and may be part of a window unit.

### CROSS-REFERENCE TO RELATED APPLICATIONS

This application claims the benefit of U.S. Provisional Application No. 63/412,129 filed on Sep. 30, 2022, the complete disclosure of which is incorporated herein by reference for all purposes.

### TECHNICAL FIELD

This description generally relates to seals for sealing the edge of laminated materials and structures, such as for example, photovoltaic laminated structures including laminated glass and laminated window units with photovoltaic features.

### BACKGROUND

Laminated window structures for vehicles and buildings can include glass and/or polymer layers that are adhered together. For example, a typical laminated window may be made of two or more glass sheets or panes that are fused together with a polymer layer or coating in between. One of the benefits of a laminated window such as this is that they do not shatter when broken like regular tempered glass window units. This is why laminated glass is sometimes referred to as safety glass. In addition, the space in between the panes can also serve as insulation. Thus, laminated windows offer better insulation than traditional single-pane windows while also providing good acoustic performance.

These laminated window structures can include functional features such as photovoltaic features. Photovoltaic features enable the window, skylight, etc. to harvest energy from the sun. It is an increasing trend to improve the overall energy efficiency of vehicles and buildings, such as with the use of photovoltaics. Luminescent solar concentrators (“LSCs”) can be incorporated into laminated materials and structures such as laminated glass windows to capture energy from the sun. For example, semiconductor nanoparticles such as quantum dots can be incorporated into laminated window structures. The quantum dots direct energy from light to photovoltaic cells for conversion into electrical energy.

Exposure to moisture can lead to delamination and other undesirable effects in laminated products. Accordingly, a seal can be employed along the edges of laminated glass products to prevent moisture from affecting the adhesion of the layers of glass and/or polymer. Such a seal can desirably also protect laminated products for window units that incorporate photovoltaic energy harvesting features from moisture as well as contamination, which would also have a negative impact on the performance of the photovoltaic energy harvesting features.

### BRIEF SUMMARY

Described herein is a seal for enclosing an edge of a laminated structure. The seal may comprise a polymeric base layer, a foil layer, and a plurality of photovoltaic cells disposed on the foil layer. The seal may be adhered to an edge of a laminate that has luminescent solar concentrators for harvesting energy from light. The laminate may be a glass laminate, and may be part of a window unit.

In accordance with one aspect, a seal is provided for enclosing an edge of a laminated structure. The seal may comprise a polymeric base layer, a foil layer adjacent the polymeric base layer, and a plurality of photovoltaic cells disposed on the foil layer. The foil layer may be on the polymeric base layer. In some embodiments, the polymeric base layer may be a dark colored polymeric material. A carrier layer may be attached to the polymeric base layer. The carrier layer, in some embodiments, may be embossed. The polymeric base layer may comprise polyurethane.

In some embodiments, the foil layer may comprise a material selected from the group consisting of aluminum, titanium, polyimide, and a metalized plastic. The foil layer may include a first side and an opposed second side. In some embodiments, the seal may include an adhesive coating that may be provided on one side or on both sides of the foil layer. This adhesive coating may comprise a clear polymeric adhesive layer. The clear adhesive layer may comprise a layer of thermoplastic polyurethane, for example.

In some embodiments, the photovoltaic cells may each include a first electrode, an alloy layer, and a second electrode. In certain embodiments, the alloy layer may include copper (Cu), Indium (In), and gallium (Ga). In some embodiments, the alloy layer may include sulfur (S). In some embodiments, the alloy layer may include selenium (Se).

In some embodiments, the alloy layer may be printed on the foil layer. The alloy layer may be printed after the first electrode is formed, in some cases. In certain embodiments, the alloy layer may include a metal such as silver, gold, aluminum, thallium, or tellurium.

In some embodiments, either one or both of the electrodes may be opaque. In some embodiments, at least one of the electrodes may be transparent. For example, one of the first or second electrodes may be transparent (the other of the two electrodes being opaque in this case), or both the first and second electrodes may be transparent.

In another aspect, a laminate may be provided. The laminate may have an edge and a seal disposed on the edge, the seal comprising a polymeric base layer, a foil layer adjacent the polymeric base layer, and a plurality of photovoltaic cells disposed on the foil layer. In some embodiments, the foil layer may be on the polymeric base layer, and the seal may be adhered to the edge.

The laminate may be a functional laminate. In some embodiments, the laminate may include a functional layer having luminescent solar concentrators (“LSCs”) disposed therein. The LSCs may be quantum dots. In some embodiments, the quantum dots each have a core and a shell. For example, the quantum dots may each have a CuIS core and a ZnS shell. The quantum dots may be configured to re-emit or convey energy, such as from absorbed radiation, to the photovoltaic cells in the seal.

In some embodiments, the laminate may also include an electrochromic assembly. In certain embodiments, the laminate may include an infrared absorbing layer. In certain embodiments, the laminate may include an infrared reflecting layer. In some embodiments, the laminate may include an electromagnetic shield. In some embodiments, the laminate may include an impact resistant layer. In certain embodiments, the laminate may include a bullet resistant layer.

In some embodiments, the laminate may include a layer selected from a group consisting of a structural polyvinyl butyral (“PVB”) or ionomer layer, an optical grade ethylene co-vinyl acetate (“EVA”) interlayer, an acoustic grade PVB interlayer, and a solar control PVB, TPU, or ionomer interlayer.

In a further aspect, a method of sealing an edge of a laminate is provided. The method may comprise: forming a base layer on a carrier layer; attaching a foil layer to the base layer to form a seal; printing a plurality of photovoltaic cells on the foil layer; and adhering the seal to the edge of the laminate. The laminate may include luminescent solar concentrators (“LSCs”). The LSCs may be quantum dots. The quantum dots may have a core and a shell. For example, the quantum dots may have a copper iodine sulfide (“CuIS”) core and a zinc sulfur shell (“ZnS”).

In some embodiments, the step of printing the plurality of photovoltaic cells may include forming a first electrode, forming an alloy layer, and forming a second electrode. In some embodiments, the laminate may include at least one pane, or more than one pane, comprising glass or polycarbonate.

In certain embodiments, a layer of thermoplastic polyurethane (“TPU”) may be formed over the foil layer. The step of adhering the seal to the edge of the laminate may include applying heat to the TPU. In some embodiments, the base layer comprises a dark colored polymeric material.

In some embodiments, the alloy layer may include copper (“Cu”), Indium (“In”) and gallium (“Ga”). In certain embodiments, the alloy layer may include sulfur (“S”). In certain embodiments, the alloy layer may include selenium(“Se”).

In a further aspect, a method of forming a seal for a laminate is provided. The method may comprise: forming a plurality of photovoltaic cells on a foil layer; forming a base layer on the foil layer; and forming an adhesive layer on the foil layer, opposite the base layer.

The photovoltaic cells may be formed by printing the photovoltaic cells on the foil layer. Printing the plurality of photovoltaic cells can include forming a first electrode, forming an alloy layer, and forming a second electrode.

In some embodiments, the base layer may be a dark colored polymeric material. In some embodiments, the alloy layer may include copper (“Cu”), Indium (“In”) and gallium (“Ga”). In some embodiments, the alloy layer can include sulfur (“S”). In some embodiments, the alloy layer can include selenium (“Se”).

In some embodiments, the base layer may be formed by casting the base layer on the foil, on a side opposite the photovoltaic cells. In certain embodiments, the adhesive layer may be formed by casting a clear aliphatic adhesive on the foil layer, opposite the base layer.

In use, the seal may be cut or slit to a required or desired width.

In still another aspect, a method of sealing an edge of a laminate is provided. The method may comprise: providing a stack of layers to form a laminate, at least one of the layers having luminescent solar concentrators (“LSC”) and another of the layers comprising a rigid pane; and wrapping an edge of the stack with a seal, the seal having photovoltaic cells therein and an adhesive layer.

In some embodiments, the laminate can include at least one pane comprising glass or polycarbonate. The luminescent solar concentrators (“LSCs”) can be quantum dots. In some embodiments, the quantum dots can each have a core and a shell. In certain embodiments, the quantum dots can each have a copper iodine sulfide (“CuIS”) core and a zinc sulfur shell (“ZnS”).

In some embodiments, wires may be soldered or otherwise attached to form electrical connections with the photovoltaic cells.

In certain embodiments, the method may further comprise autoclaving the stack. The autoclaving may laminate the layers of the stack and adhere the seal to the edge.

It is to be understood that both the foregoing general description and the following detailed description are exemplary and explanatory only and are not restrictive of the disclosure. Additional features of the disclosure will be set forth in part in the description which follows or may be learned by practice of the disclosure.

### BRIEF DESCRIPTION OF THE DRAWINGS

The accompanying drawings, which are incorporated in and constitute a part of this specification, illustrate several embodiments and together with the description serve to explain certain principles.

FIG. 1 is a schematic cross-sectional view of a seal for the edge of a laminated structure, according to an exemplary embodiment;

FIG. 1A is an enlarged view of the foil layer and photovoltaic cells of the seal of FIG. 1;

FIG. 2 is a schematic cross-sectional view of an exemplary embodiment of a laminated structure having the seal of FIG. 1 on an edge thereof;

FIG. 3 is a perspective view of an exemplary embodiment of a laminated window unit having the seal of FIG. 1 on an edge of the laminated structure; and

FIG. 4 is a schematic perspective view of an exemplary embodiment of an electrochromic assembly.

### DETAILED DESCRIPTION OF THE EMBODIMENTS

This description and the accompanying drawings illustrate exemplary embodiments and should not be taken as limiting, with the claims defining the scope of the present disclosure, including equivalents. Various mechanical, compositional, structural, and operational changes may be made without departing from the scope of this description and the claims, including equivalents. In some instances, well-known structures and techniques have not been shown or described in detail so as not to obscure the disclosure. Like numbers in two or more figures represent the same or similar elements. Furthermore, elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment. Moreover, the depictions herein are for illustrative purposes only and do not necessarily reflect the actual shape, size, or dimensions of the system or illustrated components.

It is noted that, as used in this specification and the appended claims, the singular forms “a,” “an,” and “the,” and any singular use of any word, include plural referents unless expressly and unequivocally limited to one referent. As used herein, the term “include” and its grammatical variants are intended to be non-limiting, such that recitation of items in a list is not to the exclusion of other like items that can be substituted or added to the listed items.

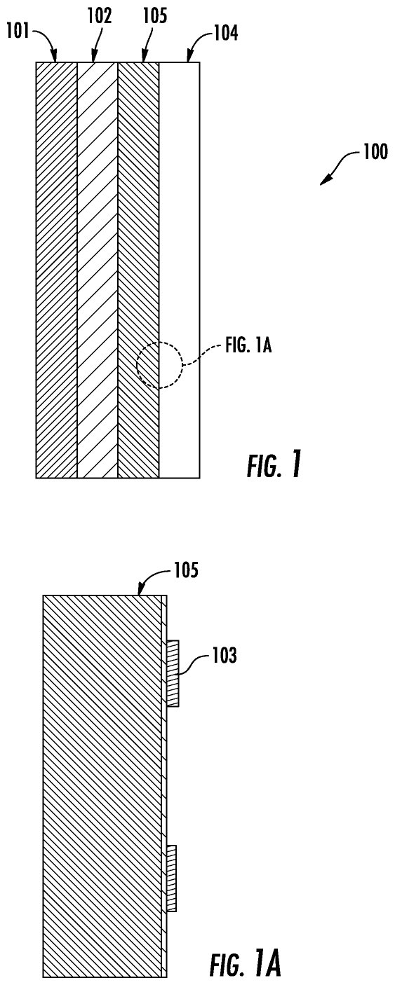

A seal 100 for an edge of a laminated structure according to an exemplary embodiment is shown in FIG. 1. The seal 100 may have a carrier layer 101. In some exemplary embodiments, this carrier layer 101 may be a clear material, and may desirably be embossed in a pattern. A base layer 102 comprising a black or dark-colored polymer film or coating, which can be polyurethane for example, may be disposed on the carrier 101. The carrier layer 101, when embossed, can impart the pattern onto the base layer 102 for aesthetic purposes, when the carrier layer 101 and base layer 102 are adhered to one another. In some embodiments, the base layer 102 can cushion the edge of the laminated structure. A foil layer 105 may be disposed on the base layer 102 for moisture and solvent resistance, and to protect the laminated structure from contamination. An adhesive layer 104 of polymeric adhesive, which in one embodiment may be a clear thermoplastic polyurethane (“TPU”), can be provided to cover the foil layer 105 and for adhering the seal 100 to the edge of the laminated structure. The carrier layer 101 may be removed and discarded when the seal is adhered to the edge of the laminated structure.

In some exemplary embodiments, the seal 100 can also include functional properties such as photovoltaic properties. The seal 100 may, for instance, include a plurality of photovoltaic cells 103 for converting energy from light to electricity. As shown in greater detail in FIG. 1A, photovoltaic cells 103 may be provided on the foil layer 105 of the seal 100 of FIG. 1. In certain embodiments, the photovoltaic cells 103 may be formed on the foil layer 105, and then the foil layer 105 is applied to base layer 102. In some embodiments, the foil layer 105, base layer 102, and carrier layer 101 can be autoclaved to form the seal 100, and then the photovoltaic cells 103 may be formed on the foil layer 105. In some embodiments, the layer of adhesive 104 may be extruded onto the foil layer 105 using a flat die. In other examples, a layer of clear polymer may be coated, cast, sprayed or otherwise formed on the foil layer 105.

In some embodiments, the foil layer 105 may be aluminum foil, and the photovoltaic cells 103 may be formed by printing or coating the foil layer 105 with an alloy layer. This alloy layer may include, for example, a mix of copper (“Cu”), Indium (“In”), and gallium (“Ga”). In certain embodiments, Cu, In, Ga, and either sulfur (“S”) or selenium (“Se”) may be printed or coated on the foil layer 105. The photovoltaic cells 103 may be formed from a first electrode, the alloy layer, and a transparent electrode to complete the cells so that the cells can convert the energy absorbed from light to electrical energy. In some embodiments, a plurality of photovoltaic cells 103 may be formed on the foil layer 105 in one or more rows, clusters, or in an array or pattern, such as a predetermined geometric pattern.

In some embodiments, the alloy layer can include a combination of Cu, silver (“Ag”), gold (“Au”), Ga, In, aluminum (“Al”), thallium (“Ti”), Se, S, and/or tellurium (“Te”). The alloy can be, for example, printed on the foil layer 105 using equipment similar to a printing press. The foil layer 105 may be provided in a roll and printed with the alloy. Other types of photovoltaic cells 103 may be formed on the foil layer 105 by coating, printing, or spraying.

In certain embodiments, the seal 100 may not have a polymeric adhesive layer 104, and instead, the seal may be adhered to the edge of the laminate using other materials.

In some embodiments, the foil layer 105 can be titanium, a polymer such as for example polyimide, or a metallized plastic. The first electrode, in embodiments, may be an electrically conductive stainless steel or molybdenum. The second electrode may be a transparent electrode, in embodiments, such as a transparent conductive film. In certain embodiments, at least one of the first electrode and second electrode may be made from transparent conductive films. Transparent conductive films are used in a variety of electronic devices such as photovoltaics, touch screens and displays. One example is indium tin oxide (“ITO”), which is very commonly used in electronic devices. Others include transparent conductive oxides (“TCO”), conductive polymers, metal meshes, carbon nanotubes (“CNT”), graphene, nanowires, and ultra-thin metal films.

In some embodiments, the transparent electrode or electrodes may include carbon nanotubes. In certain embodiments, the transparent electrodes may be made from nanotube hybrids, which combine carbon nanotubes with another element, such as carbon, graphite, silver, or copper.

In some embodiments, the photovoltaic cells 103 may be silicon photovoltaic cells, organic solar cells, or another type of photovoltaic cell.

In some embodiments, adhesive layer 104 can be an encapsulant layer, such as one or more layers of polyethylene terephthalate (“PET”), ethylene vinyl acetate (“EVA”), or other polymers.

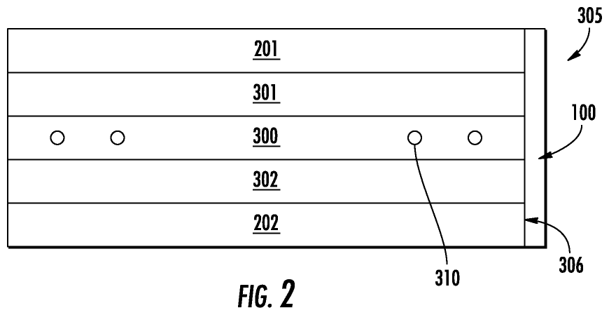

An exemplary embodiment of a laminate 305 for a window unit is shown in FIG. 2. The laminate 305 may have functional properties, and as such, may include a photovoltaic layer 300 that redirects incident radiation, or more specifically incident solar radiation. Photovoltaic layer 300 may be a polymeric material having luminescent solar concentrators (“LSC”) 310 disposed therein. The polymeric material, in some embodiments, may be a thermoplastic polyurethane (“TPU”), an ethylene co-vinyl acetate (“EVA”), a plasticized polyvinyl butyral or a polymethyl methacrylate (“PMMA”). The polymeric material can be extruded in a single screw or two screw extrusion, cast, coated, UV cured, or formed in other methods. It should be understood that the LSCs 310 are not visible (in FIG. 2, the LSCs are shown schematically). For example, the layer 300 can have quantum dots which, due to their size and structure, can absorb part of incident solar radiation and re-emit in an emission band with large Stokes shift. The re-emitted emission may be harvested by the photovoltaic cells 103 in the seal 100 on the edge of the laminate 305. In some embodiments, the seal 100 may be applied on the long edges of the laminate 305.

The photovoltaic layer 300 may have polymeric adhesive material extruded or otherwise formed thereon, preferably on both of the major sides of the photovoltaic layer 300. For example, in the exemplary embodiment shown in FIG. 2, a first layer of clear TPU 301 and a second layer of clear TPU 302 may be disposed on the photovoltaic layer 300. This subassembly can be laminated with rigid panes of glass or polymer in an autoclave or non-autoclave process. In the exemplary embodiment of FIG. 2, the laminate 305 may have a first pane 201 and a second pane 202. One or more edges 306 of the laminate 305 may have the seal 100 applied thereto, to protect the laminate 305 from moisture or other contaminants, as the application of heat or heat and pressure will activate the adhesive TPU 301, 302. In another embodiment (not shown), the photovoltaic layer 300 itself may act as the adhesive interlayer bonding a first rigid pane 201 and a second rigid pane 202, thereby eliminating the need for separate adhesive layers 301 and 302.

In some embodiments, the solar concentrators 310 of the laminate 305 can be luminophores that absorb the majority of near infrared (“NIR”) or ultraviolet (“UV”) photons and reemit with a Stokes shift of greater than 200 nanometers.

In one embodiment, the highest performance LSCs 310 can utilize phosphorescent organic molecules or blends of multiple fluorophores (such as quantum dots or organic dyes) that act to reduce reabsorption losses and enhance overall absorption efficiencies across the spectrum.

In some embodiments, the luminophores may have a structure selected from MX2 L2, AMX2L2, M6X12L2, A2M6X14, and A2M6X14.L2, where M=W or Mo, X═Cl, Br, or I, L=Cl, CH₃CN, a benzenethiol, ethanethiol, H₂O (hydrate), HCl, and acetonitrile, and A=K, Na, tetrabutylammonium (“TBA”), and other ammonium salts. Other structures are contemplated.

In yet further embodiments, the plurality of luminophores may include quantum dots with core/shell structure. For example, the core/shell structures can be: CdSe/CdS, CdSe/ZnSe, CdSe/ZnS, CdSe/ZnTe, CdSe/CdTe, CdTe/CdSe, CdTe/CdS, CdTe/ZnSe, CdTe/ZnS, CdTe/ZnTe, CdS/ZnSe, CdS/ZnS, CdS/CdTe, CdS/CdSe, PbSe/PbS, PbS/PbSe, PbTe/PbS, PbS/PbTe, PbTe/PbSe, PbSe/PbTe, PbSe/CdSe, CdSe/PbTe, PbS/CdS, CdS/PbS, PbTe/CdTe, CdTe/PbTe, InAs/CdS, InSb/CdS, InP/CdS, InAs/CdSe, InSb/CdSe, InP/CdSe, InAs/ZnSe, InP/ZnSe, InSb/ZnSe, InAs/ZnS, InP/ZnS, InSb/ZnS, Ge/Si, Si/Ge, Sn/Si, Si/Sn, Ge/Sn, or Sn/Ge.

In some embodiments, the laminate 305 may have a low haze and high visible light transmissivity suitable for use in a window. For example, the haze may be less than 7% (as measured according to ASTM D1003). In further examples, the haze may be less than 3%, and, in other examples, less than 1%. In some embodiments, visible light transmission may be more than 30% (as measured according to ASTM D1003). In other examples, the visible light transmission may be greater than 50% and in other examples, greater than 70%.

Suitable quantum dots may be quantum dots having a copper iodine sulfur (“CuIS”) core and a zinc sulfur (“ZnS”) shell. Other quantum dots, including hybrid quantum dots, are contemplated. In some embodiments, the laminate 305 may have an edge 306, and the seal 100 may be adhered to the edge 306 of the laminate 305, as shown in FIG. 2.

An exemplary method of forming a seal for a laminate may include: printing a plurality of photovoltaic (“PV”) cells on a foil layer; casting a base layer on the non-PV side of the foil; casting a clear aliphatic adhesive layer on the PV side of the foil; and cutting or slitting the film to the required or desired width.

The steps involved in preparing the seal can be performed by a manufacturer and provided to a laminator. The laminator can apply the seal to a laminate or, in some embodiments, apply the seal to a stack and laminate the stack while also adhering the seal. An exemplary method of sealing an edge of a laminate with photovoltaic functions as described herein may include: wrapping an edge or edges with the seal; soldering wires (or otherwise forming and/or attaching wires) to provide electrical connections to the photovoltaic cells in the seal; and autoclaving the assembly to bond the layers of the laminate, and also to bond the seal with the laminate edge or edges.

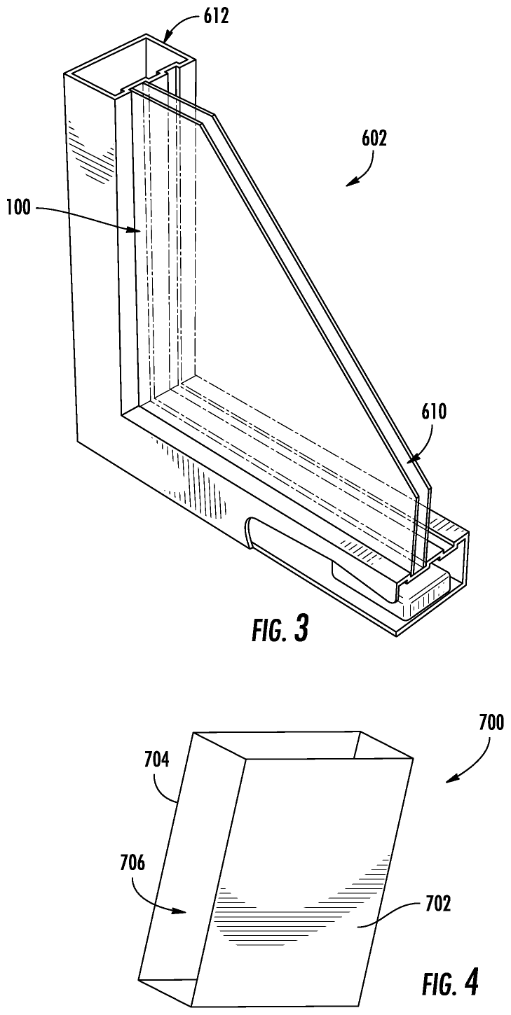

An exemplary embodiment of a window unit 602 is shown in FIG. 3. The window unit 602 includes a laminate 610 provided in a frame 612, with one or more edges of the laminate 610 protected by the seal 100 or seals, and having photovoltaic cells incorporated in the seal 100. In some embodiments, the laminate 610 of the window unit 602 can be similar to the laminate 305 discussed above in connection with FIG. 2. It is contemplated that, in this embodiment, the foil layer 105 of the applied seal 100 can function both as a moisture-resistant layer for the window unit 602 and the base foil for the formation of the photovoltaic cells. The LSCs 310, such as semiconductor nanoparticles, in the photovoltaic layer 300 can direct energy captured from light to the photovoltaic cells 103 in the seal 100. This avoids having to provide a seal for the laminate edge and separately adding photovoltaic cells to the assembly. In certain embodiments, the photovoltaic cells may be electrically connected to one or more wires, traces, bus bars, etc. to deliver the electrical energy generated to a battery, electrical devices, etc.

In some embodiments, the laminate 305 for the window unit 602 may include one or more layers selected from bullet resistant layers, impact resistant layers, electromagnetic shield layers, infrared absorbing layers, infrared reflective layers, and electrochromic assemblies. Such layers may, for example, include:
1) a standard polyvinyl butyral (“PVB”) interlayer containing 38 phr triethylene glycol bis(2-ethylhexanoate) plasticizer;
2) an acoustic grade PVB interlayer such as Eastman Saflex Q-series®, Eastman Saflex E-series®, Seksisui S-Lec® and Kuraray Acoustic-grade Tosifol®;
3) solar control PVB, TPU or ionomeric interlayer to reduce heat gain;
4) a Structural PVB interlayer containing 20 phr triethylene glycol bis(2-ethylhexanoate);
5) structural ionomer such as Kuraray's SentryGlas Plus; or
6) an optical grade EVA interlayer.

FIG. 4 illustrates an exemplary embodiment of an electrochromic assembly 700 that may be incorporated into a laminate for a window unit. As shown, the electrochromic assembly 700 may include first electrode 702 and second electrode 704. In some embodiments, the first electrode 702 and second electrode 704 may both be transparent. An ion conducting layer 706 may be disposed therebetween 706, as shown in FIG. 4. The electrochromic assembly 700 can be provided to control the light transmissivity of the laminate and window unit. In an exemplary embodiment, the ion conducting layer 706 may be an interlayer film having a lithium salt provided in a polymer layer such as, for example, TPU, EVA, or PMMA.

In some embodiments, the ion conducting interlayer film 706 may be extruded and laminated with other layers of the laminate. In certain other embodiments, a polymer can be plasticized with a liquid electrolyte. For example, TPU can be plasticized with polypropylene carbonate containing a lithium salt. For better transparency, particular organic carbonates can be used as the plasticizer. In an example, an organic carbonate and a dibenzoate or acrylic monomer can be used as the plasticizer, with TPU or PMMA and a lithium salt. In other embodiments, the ion conducting layer can be cast, coated, UV cured, or formed using other methods. The electrodes 702, 704, in some embodiments, transparent electrode layers formed as discussed above. The electrochromic assembly 700 can be combined with laminate 305 and used in a window unit. The photovoltaic layer 300 can be used to provide power to the electrochromic assembly 700, in some embodiments, or a separate source of power can be used.

Other embodiments will be apparent to those skilled in the art from consideration of the specification and practice of the embodiment disclosed herein. It is intended that the specification and examples be considered as exemplary only, with a true scope and spirit of the embodiment being indicated by the following claims.

For example, according to one aspect, in a 1^{st} embodiment, a seal is provided for enclosing an edge of a laminated structure. The seal comprises a polymeric base layer, a foil layer adjacent the polymeric base layer, and a plurality of photovoltaic cells disposed on the foil layer.

A 2^{nd} embodiment is the 1^{st} embodiment, wherein the polymeric base layer comprises a dark colored polymeric material.

A 3^{rd} embodiment is any combination of the first 2 embodiments, further comprising a carrier layer attached to the polymeric base layer.

A 4^{th} embodiment is any combination of the first 3 embodiments, wherein the carrier layer is embossed.

A 5^{th} embodiment is any combination of the first 4 embodiments, wherein the polymeric base layer comprises polyurethane.

A 6^{th} embodiment is any combination of the first 5 embodiments, wherein the foil layer comprises a material selected from the group consisting of aluminum, titanium, polyimide, and a metalized plastic.

A 7^{th} embodiment is any combination of the first 6 embodiments, wherein the foil layer includes a first side and an opposed second side, and further including an adhesive coating on at least one side of the foil layer.

An 8^{th} embodiment is any combination of the first 7 embodiments, wherein the adhesive coating comprises a clear polymeric adhesive layer.

A 9^{th} embodiment is any combination of the first 8 embodiments, wherein the clear polymeric adhesive layer comprises a layer of thermoplastic polyurethane.

A 10^{th} embodiment is any combination of the first 9 embodiments, wherein the photovoltaic cells each include a first electrode, an alloy layer, and a second electrode.

An 11^{th} embodiment is any combination of the first 10 embodiments, wherein the alloy layer includes copper (Cu), Indium (In), and gallium (Ga).

A 12^{th} embodiment is any combination of the first 11 embodiments, wherein the alloy layer includes sulfur (S).

A 13^{th} embodiment is any combination of the first 12 embodiments, wherein the alloy layer includes selenium (Se).

A 14^{th} embodiment is any combination of the first 13 embodiments, wherein the alloy layer is printed on the foil layer.

A 15^{th} embodiment is any combination of the first 14 embodiments, wherein the alloy layer is printed after the first electrode is formed.

A 16^{th} embodiment is any combination of the first 15 embodiments, wherein the alloy layer includes a metal selected from the group consisting of silver, gold, aluminum, thallium, and tellurium.

A 17^{th} embodiment is any combination of the first 16 embodiments, wherein at least one of the first and second electrodes is transparent.

An 18^{th} embodiment is any combination of the first 17 embodiments, wherein at least one of the first and second electrodes is opaque.

In a second aspect, a 1^{st} embodiment of a laminate having an edge is provided, and a seal according to any combination of the first 18 embodiments disposed on the edge.

A 2^{nd} embodiment is the laminate of the 1^{st} embodiment, wherein the seal is adhered to the edge.

A 3 ^{rd} embodiment of the laminate is any combination of the previous 2 embodiments, wherein the laminate includes a functional layer having luminescent solar concentrators (“LSCs”) disposed therein.

A 4^{th} embodiment of the laminate is any combination of the previous 3 embodiments, wherein the LSCs are quantum dots.

A 5^{th} embodiment of the laminate is any combination of the previous 4 embodiments, wherein the quantum dots each have a core and a shell.

A 6^{th} embodiment of the laminate is any combination of the previous 5 embodiments, wherein the core is a CuIS core and the shell is a ZnS shell.

A 7^{th} embodiment of the laminate is any combination of the previous 6 embodiments, wherein the quantum dots are configured to re-emit absorbed radiation to the photovoltaic cells in the seal.

An 8^{th} embodiment of the laminate is any combination of the previous 7 embodiments, further including an electrochromic assembly.

A 9^{th} embodiment of the laminate is any combination of the previous 8 embodiments, further including an infrared absorbing layer.

A 10^{th} embodiment of the laminate is any combination of the previous 9 embodiments, further including an infrared reflecting layer.

An 11^{th} embodiment of the laminate is any combination of the previous 10 embodiments, further including an electromagnetic shield.

A 12^{th} embodiment of the laminate is any combination of the previous 11 embodiments, further including an impact resistant layer.

A 13^{th} embodiment of the laminate is any combination of the previous 12 embodiments, further including a bullet resistant layer.

A 14^{th} embodiment of the laminate is any combination of the previous 13 embodiments, wherein the laminate includes a layer selected from a group consisting of a structural polyvinyl butyral (“PVB”) or ionomer layer, an optical grade ethylene co-vinyl acetate (“EVA”) interlayer, an acoustic grade PVB interlayer, and a solar control PVB, TPU, or ionomer interlayer.

In a third aspect, a 1^{st} embodiment of a method of sealing an edge of a laminate is provided. The method comprises: forming a base layer on a carrier layer; attaching a foil layer to the base layer to form a seal; printing a plurality of photovoltaic cells on the foil layer; and adhering the seal to the edge of the laminate.

A 2^{nd} embodiment is the method of the 1^{st} embodiment, wherein the laminate includes luminescent solar concentrators (“LSCs”).

A 3^{rd} embodiment is the method of the previous 2 embodiments, wherein the LSCs are quantum dots.

A 4^{th} embodiment is the method of the previous 3 embodiments, wherein the quantum dots each have a core and a shell.

A 5^{th} embodiment is the method of the previous 4 embodiments, wherein the quantum dots each have a copper iodine sulfide (“CuIS”) core and a zinc sulfur shell (“ZnS”).

A 6^{th} embodiment is the method of the previous 5 embodiments, wherein printing the plurality of photovoltaic cells includes forming a first electrode, forming an alloy layer, and forming a second electrode.

A 7^{th} embodiment is the method of the previous 6 embodiments, wherein the laminate includes at least one pane selected from the group consisting of glass and polycarbonate.

An 8^{th} embodiment is the method of the previous 7 embodiments, further comprising forming a layer of thermoplastic polyurethane (“TPU”) over the foil layer.

A 9^{th} embodiment is the method of the previous 8 embodiments, wherein adhering the seal to the edge of the laminate includes applying heat to the TPU.

A 10^{th} embodiment is the method of the previous 9 embodiments, wherein the base layer comprises a dark colored polymeric material.

An 11^{th} embodiment is the method of the previous 10 embodiments, wherein the alloy layer includes copper (“Cu”), Indium (“In”) and gallium (“Ga”).

A 12^{th} embodiment is the method of the previous 11 embodiments, wherein the alloy layer includes sulfur (“S”).

A 14^{th} embodiment is the method of the previous 12 embodiments, wherein the alloy layer includes selenium (“Se”).

In a fourth aspect, a 1^{st} embodiment of a method of forming a seal for a laminate is provided. The method comprises: forming a plurality of photovoltaic cells on a foil layer; forming a base layer on the foil layer; and forming an adhesive layer on the foil layer, opposite the base layer.

A 2^{nd} embodiment is the method of the 1^{st} embodiment, wherein the photovoltaic cells are formed by printing the photovoltaic cells on the foil layer.

A 3^{rd} embodiment is the method of the previous 2 embodiments, wherein printing the plurality of photovoltaic cells includes forming a first electrode, forming an alloy layer, and forming a second electrode.

A 4^{th} embodiment is the method of the previous 3 embodiments, wherein the base layer is a dark colored polymeric material.

A 5^{th} embodiment is the method of the previous 4 embodiments, wherein the alloy layer includes copper (“Cu”), Indium (“In”) and gallium (“Ga”).

A 6^{th} embodiment is the method of the previous 5 embodiments, wherein the alloy layer includes sulfur (“S”).

A 7^{th} embodiment is the method of the previous 6 embodiments, wherein the alloy layer includes selenium (“Se”).

An 8^{th} embodiment is the method of the previous 7 embodiments, wherein the base layer is formed by casting the base layer on the foil, on a side opposite the photovoltaic cells.

A 9^{th} embodiment is the method of the previous 8 embodiments, wherein the adhesive layer is formed by casting a clear aliphatic adhesive on the foil layer, opposite the base layer.

A 10^{th} embodiment is the method of the previous 9 embodiments, further comprising cutting the seal to a desired width.

In a fifth aspect, a 1^{st} embodiment of a method of sealing an edge is provided. The method comprises: providing a stack of layers to form a laminate, at least one of the layers having luminescent solar concentrators, and another of the layers comprising a rigid pane; and wrapping an edge of the stack with a seal, the seal having photovoltaic cells therein and an adhesive layer.

A 2^{nd} embodiment is the method of the 1^{st} embodiment, wherein the laminate includes at least one pane comprising glass or polycarbonate.

A 3^{rd} embodiment is the method of the previous 2 embodiments, wherein the luminescent solar concentrators (“LSCs”) are quantum dots.

A 4^{th} embodiment is the method of the previous 3 embodiments, wherein the quantum dots each have a core and a shell.

A 5^{th} embodiment is the method of the previous 4 embodiments, wherein the quantum dots each have a copper iodine sulfide (“CuIS”) core and a zinc sulfur shell (“ZnS”).

A 6^{th} embodiment is the method of the previous 5 embodiments, further comprising soldering wires to form electrical connections with the photovoltaic cells.

A 7^{th} embodiment is the method of the previous 6 embodiments, further comprising autoclaving the stack.

An 8^{th} embodiment is the method of the previous 7 embodiments, wherein autoclaving laminates the layers of the stack and adheres the seal to the edge.

What is claimed is:

1. A seal comprising a polymeric base layer, a foil layer adjacent the polymeric base layer, and a plurality of photovoltaic cells disposed on the foil layer.

2. The seal according to claim 1, wherein the polymeric base layer comprises a dark colored polymeric material.

3. The seal according to claim 1, further comprising a carrier layer attached to the polymeric base layer.

4. The seal according to claim 1, wherein the carrier layer is embossed.

5. The seal according to claim 1, wherein the polymeric base layer comprises polyurethane.

6. The seal according to claim 1, wherein the foil layer comprises a material selected from the group consisting of aluminum, titanium, polyimide, and a metalized plastic.

7. The seal according to claim 1, wherein the foil layer includes a first side and an opposed second side, and further including an adhesive coating on at least one side of the foil layer.

8. The seal according to claim 7, wherein the adhesive coating comprises a clear polymeric adhesive layer.

9. The seal according to claim 8, wherein the clear polymeric adhesive layer comprises a layer of thermoplastic polyurethane.

10. The seal according to claim 1, wherein the photovoltaic cells each include a first electrode, an alloy layer, and a second electrode.

11. The seal according to claim 10, wherein the alloy layer includes copper (Cu), Indium (In), and gallium (Ga).

12. The seal according to claim 10, wherein the alloy layer includes sulfur (S).

13. The seal according to claim 10, wherein the alloy layer includes selenium (Se).

14. The seal according to claim 10, wherein the alloy layer is printed on the foil layer.

15. The seal according to claim 14, wherein the alloy layer is printed after the first electrode is formed.

16. The seal according to claim 10, wherein the alloy layer includes a metal selected from the group consisting of silver, gold, aluminum, thallium, and tellurium.

17. The seal according to claim 10, wherein at least one of the first and second electrodes is transparent.
